(19) United States
(12) Patent Application Publication
(10) Pub. No.: US 2015/0194944 A1
(43) Pub. Date: Jul. 9, 2015

(54) WIDEBAND MATCHING NETWORK

(71) Applicant: QUALCOMM INCORPORATED, San Diego, CA (US)

(72) Inventors: Alok Joshi, Bangalore (IN); Gireesh Rajendran, Bangalore (IN); Apu Sivadas, Bangalore (IN)

(73) Assignee: QUALCOMM INCORPORATED, San Diego, CA (US)

(21) Appl. No.: 14/151,596

(22) Filed: Jan. 9, 2014

(51) Int. Cl. H03H 7/38; H03H 7/42

(52) U.S. Cl. CPC H03H 7/38; H03H 7/42

(57) ABSTRACT

Exemplary embodiments are related to wideband matching devices. A device may include a primary winding including a first plurality of inductors in series and a first switch coupled to the primary winding and configured to tune the primary winding to a frequency band of a plurality of frequency bands. The device may also include a secondary winding including a second plurality of inductors in series and a second switch coupled to the secondary winding and configured to tune the secondary winding to the frequency band.

### BACKGROUND

1. Field

The present invention relates generally to impedance matching within a wireless communication device.

2. Background

A wireless communication device (e.g., a cellular phone or a smart phone) in a wireless communication system may transmit and receive data for two-way communication. The wireless communication device may include a transmitter for data transmission and a receiver for data reception. For data transmission, the transmitter may modulate a radio-frequency (RF) carrier signal with data to obtain a modulated signal, amplify the modulated signal to obtain an output RF signal having the proper output power level, and transmit the output RF signal via an antenna to a base station. For data reception, the receiver may obtain a received RF signal via the antenna and may condition and process the received RF signal to recover data sent by the base station.

The transmitter may include various circuits such as a power amplifier (PA), a filter, etc. The receiver may also include various circuits such as a low noise amplifier (LNA), a filter, etc. An antenna tuner (i.e. impedance matching circuit) may be coupled between the antenna and the transmitter and/or the receiver and may perform tuning (i.e. impedance matching) for the antenna, the power amplifier, or the LNA. The impedance matching circuit may have a large impact on the performance of the wireless communication device.

Transmitters often incorporate a balun for converting a differential signal into a single-ended signal. For example, wireless transmit circuitry may employ a balun for converting a differential signal generated by the wireless transmit circuitry into a single-ended signal for further amplification and transmission over a wireless channel. A common balun implementation includes two mutually coupled inductive elements, configured such that a differential voltage across the first (primary) balun element generates a corresponding single-ended voltage across the second (secondary) balun element. A balun is usually either placed at the antenna feed, prior to interfacing with active elements (i.e., the elements for processing the signals transmitted and received over an antenna) or directly implemented as an active element.

A need exists for an enhanced communication device. More specifically, a need exists for enhanced impedance matching within a radio-frequency circuit of a wireless communication device.

### BRIEF DESCRIPTION OF THE DRAWINGS

FIG. 1 illustrates a device including a balun architecture.

FIG. 2 illustrates another device including a balun architecture.

FIG. 3A depicts a device including an RF module, in accordance with an exemplary embodiment of the present invention.

FIG. 3B illustrates an RF module including a transceiver, in accordance with an exemplary embodiment of the present invention.

FIG. 4A illustrates a device including a primary winding including a first plurality of coils and a secondary winding including a second plurality of coils, according to an exemplary embodiment of the present invention.

FIG. 4B illustrates another device including a primary winding including a first plurality of coils and a secondary winding including a second plurality of coils, in accordance with an exemplary embodiment of the present invention.

FIG. 5 depicts a balun including a primary winding and a secondary winding, in accordance with an exemplary embodiment of the present invention.

FIG. 6 is a plot illustrating an insertion loss for a first balun configuration and an insertion loss for a second balun configuration

FIG. 7 is a flowchart depicting a method, in accordance with an exemplary embodiment of the present invention.

FIG. 8 is a flowchart depicting another method, in accordance with an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

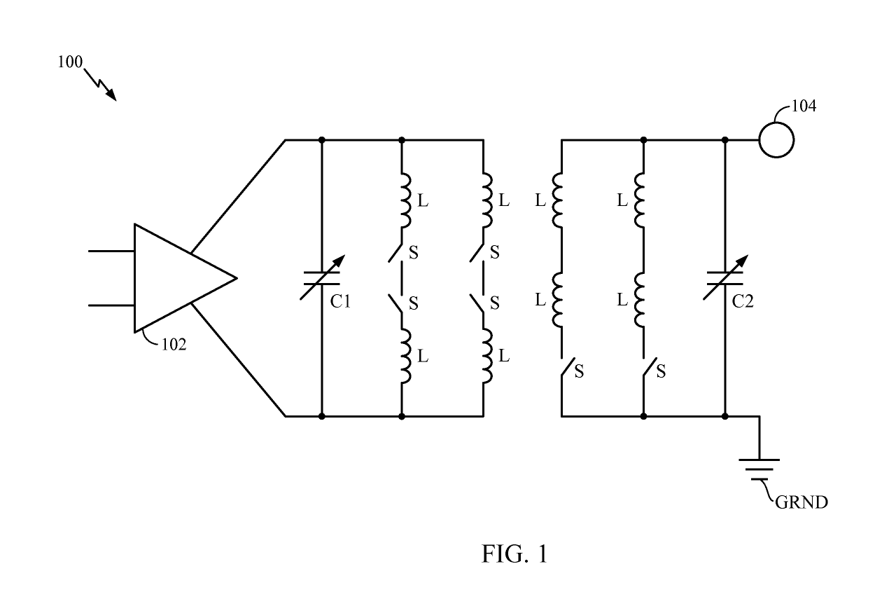

As will be appreciated by a person having ordinary skill in the art, impedance matching multiple cellular frequency bands with a single balun topology may be challenging. FIG. 1 below illustrates a conventional device 100 for driving a power amplifier within a transmitter of a wireless communication device. Device 100 includes a balun architecture, which includes capacitors C1 and C2, a plurality of inductors L, and a plurality of switches S. Further, device 100 includes a Gilbert cell mixer 102 and may be configured for receiving an input at Gilbert cell mixer 102 and conveying an output via output 104. It is noted that device 100 may include an RF amplifier in place of, or in addition to, Gilbert cell mixer 102. As will be appreciated by a person having ordinary skill in the art, Gilbert cell mixer 102 may be used to drive an external power amplifier (not shown in FIG. 1), and the balun architecture may be required for common mode noise rejection and differential-to-single (D2S) conversion.

By engaging various inductors of device 100, tuning for three distinct frequency bands can be achieved. Although a wide tuning range can be achieved, silicon area increases due to two separate coils used. Furthermore, switches S, which are used to engage or disengage inductors, may be subjected to full signal swing when an inductor is inactive, which may cause distortion and reliability issues. Also, due to requiring two switches for differential implementation, insertion loss increases and floor planning complexity may also increase.

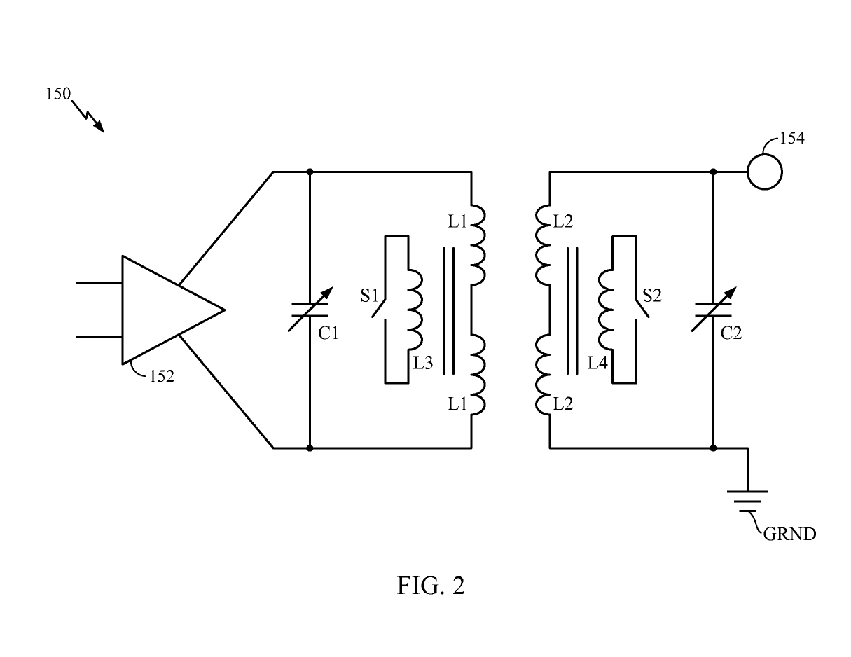

FIG. 2 illustrates another conventional device 150 for driving a power amplifier within a transmitter of a wireless communication device. Device 150 includes a balun architecture comprising capacitors C1 and C2, inductors L1-L4, and switches S1 and S2. Moreover, device 150 includes a Gilbert cell mixer 152 and may be configured for receiving an input at Gilbert cell mixer 152 and conveying an output via output 154. It is noted that device 150 may include an RF amplifier in place of, or in addition to, Gilbert cell mixer 152. As will be understood by a person having ordinary skill in the art, Gilbert cell mixer 152 may be used to drive an external power amplifier (not shown in FIG. 2) and the balun architecture may be required for common mode noise rejection and D2S conversion. Inductors L3 and L4 are coupled to mixer inductors L1 and antenna inductors L2, respectively.

By closing switches S1 & S2, values of inductors L1 and L2 may be decreased, and hence, multiband tuning may be achieved. After closing of switches S1 and S2, the inductor values of L1 and L2 reduce by a factor of 1-k*k, where k is a coupling coefficient. However, inductors L3 & L4 significantly load primary inductors L1 & L2, which may increase insertion loss. For example, for 1:2 tuning range, value of inductors L1 and L2 drop to one-fourth of their original value, which may increase insertion loss by roughly 6 dB due to Q falling to one-fourth of its original value.

Exemplary embodiments, as described herein, are directed to a device, which may be configured for wideband matching within a wireless communication device. The device, which may comprise a single, area efficient, balun, may include a single reactive passive element and be configured for providing impedance matching for multiple cellular frequency bands. By way of example, and not limitation, the device may be configured for impedance matching a frequency range of substantially 600 MHz to 2.9 GHz. As a more specific example, the device may be configured to provide matching for a power amplifier (PA) of a wireless transmitter.

It is noted that although some of the exemplary embodiments of the present invention are described herein as being implemented with a wireless transmitter, the present invention is not so limited. Rather, the present invention may be applied to any RF circuit that requires wideband tuning. As non-limiting examples, the device may provide tuning (i.e., matching) for mixers, RF amplifiers, voltage controlled oscillators (VCOs), and the like.

According to one exemplary embodiment, a device may include a primary winding including a first plurality of inductors in series. Further, the device may include a first switch coupled to the primary winding and configured to tune the primary winding according to a selected frequency band. In addition, the device may include a secondary winding including a second plurality of inductors in series. The device may also include a second switch coupled to the secondary winding and configured to tune the secondary winding according to the selected frequency band.

According to another exemplary embodiment, the present invention includes methods for wideband tuning. Various embodiments of such a method may include tuning a primary winding including a plurality of inductors in series according to a selected frequency band via a first switch coupled to the primary winding. The method may further include tuning a secondary winding including a second plurality of inductors in series according to the selected frequency band via a second switch coupled to the secondary winding.

Other aspects, as well as features and advantages of various aspects, of the present invention will become apparent to those of skill in the art through consideration of the ensuing description, the accompanying drawings and the appended claims.

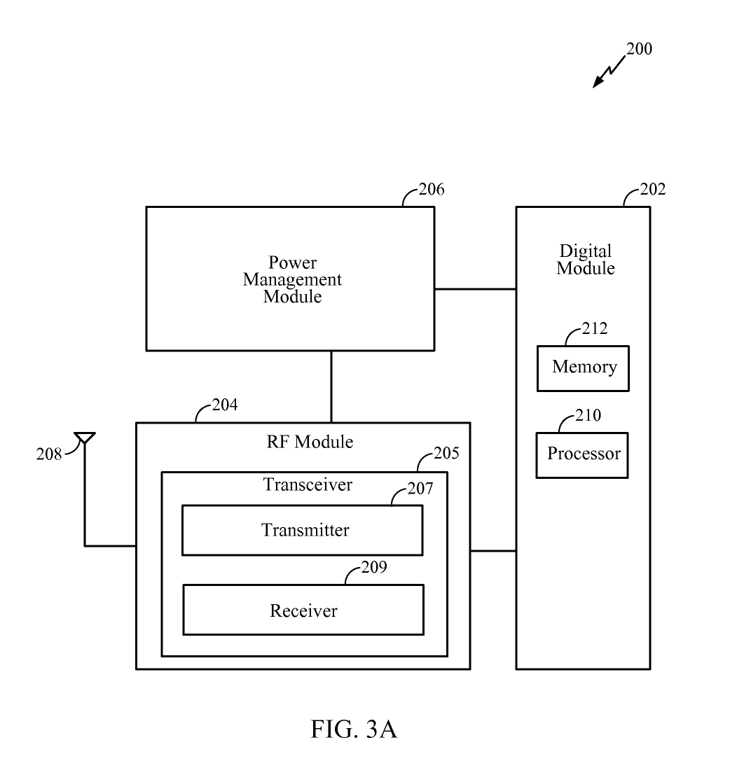

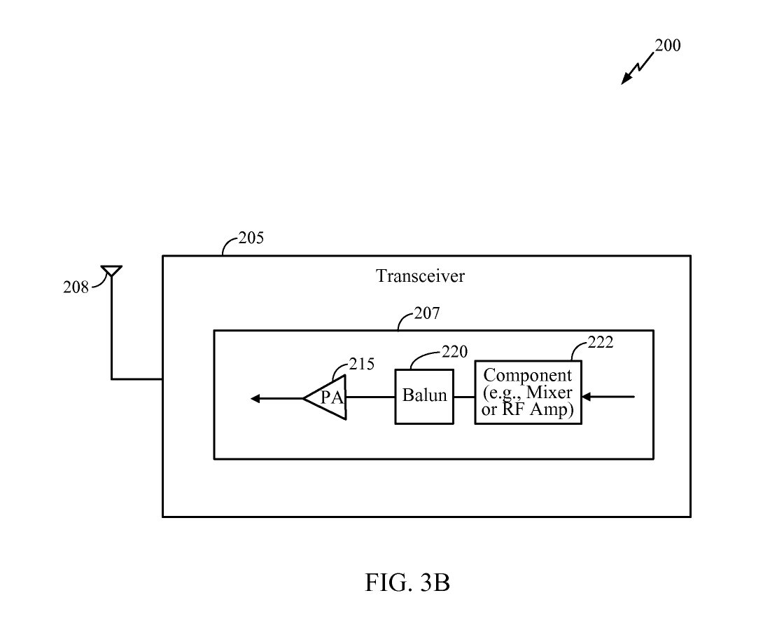

FIG. 3A is a block diagram of an electronic device 200, according to an exemplary embodiment of the present invention. According to one example, electronic device 200 may comprise a portable electronic device, such as a mobile telephone. Electronic device 200 may include various modules, such as a digital module 202, an RF module 204, and a power management module 206.

Digital module 202 may comprise one or more processors 210 and memory 212.

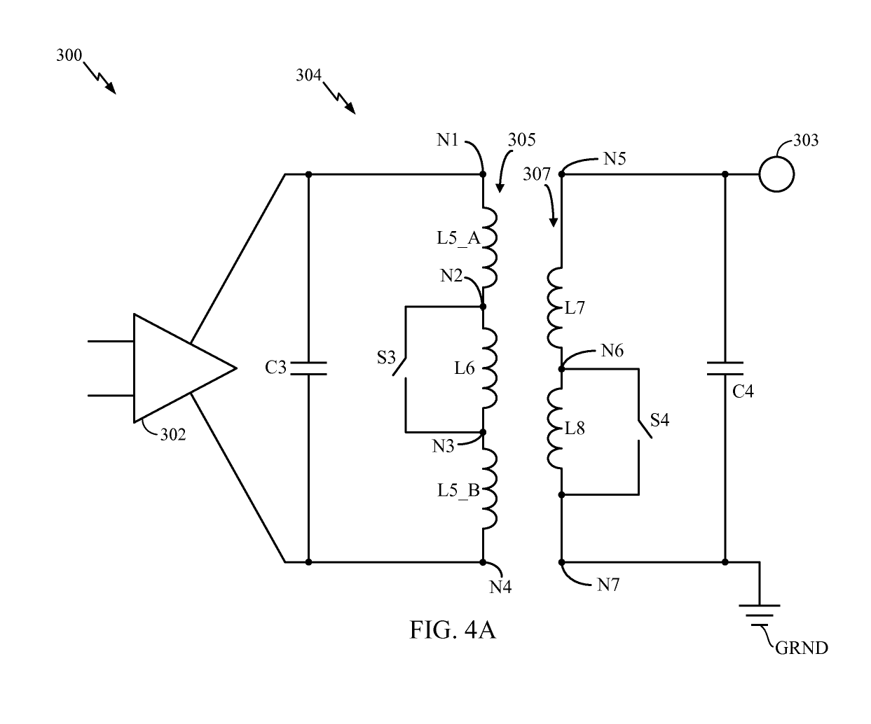

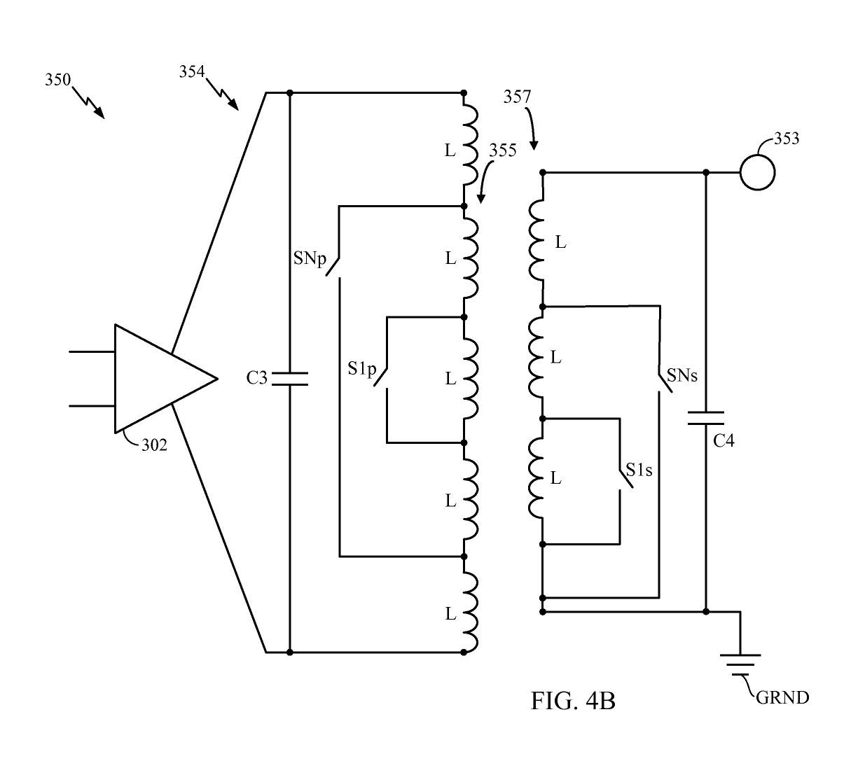

RF module 204, which may comprise RF circuitry, may include a transceiver 205 including a transmitter 207 and a receiver 209 and may be configured for bi-directional wireless communication via an antenna 208. In general, electronic device 200 may include any number of transmitters and any number of receivers for any number of communication systems, any number of frequency bands, and any number of antennas. Further, according to an exemplary embodiment of the present invention, RF module 204, which may comprise, for example, a RF integrated circuit (RFIC), may include one or more of devices 300 (see FIG. 4), as described herein.

FIG. 3B is a more detailed illustration of transceiver 205, in accordance with an exemplary embodiment of the present invention. Transceiver 205 includes transmitter 207 and may be configured for wireless communication via antenna 208. According to one exemplary embodiment of the present invention, transmitter 207 may include various RF components, such as a power amplifier 215 and a component 222, which may comprise, for example only, a mixer or an RF amplifier. Further, transmitter 207 includes a balun architecture 220, which may comprise device 304 illustrated in FIG. 4A or device 354 illustrated in FIG. 4B. In the exemplary embodiment illustrated in FIG. 3B, balun architecture 220 may be configured to provide tuning for power amplifier 215. However, the present invention is not so limited. Rather, balun architecture 220 may be configured to provide tuning for any RF circuitry (e.g., within a transmitter or a receiver), such as mixers, RF amplifiers, VCOs, and the like.

FIG. 4A illustrates a device 300, according to an exemplary embodiment of the present invention. Device 300, which may comprise, for example only, a matching network, may also include a mixer 302 coupled to a device 304. Device 300 may be configured for receiving an input at mixer 302 and conveying an output via output 303. By way of example only, mixer 302 may comprise a Gilbert cell mixer. It is noted that device 300 may include an RF amplifier in place of, or in addition to, mixer 302. Device 304, which is coupled to an output of mixer 302, includes capacitors C3 and C4, inductors L5_A, L5_B, and L6-L8, and switches S3 and S4. Each of inductors L5_A, L5_B and L6-L8 may also be referred to herein as a “coil.” Further, device 304 may also be referred to herein as a “balun architecture” or a “balun.” Device 304 can be used for high power applications and can be extended to any circuit realization (e.g., VCOs, LNAs, power amplifiers, etc).

As illustrated in FIG. 4A, device 304 includes a primary winding 305 including a plurality of inductors (i.e., inductor L6 coupled between two L5 inductors) in series and a secondary winding 307 including a plurality of inductors in series (i.e., inductors L7 and L8). A first inductor L5_A is coupled between a node N1 and a node N2, inductor L6 is coupled between node N2 and a node N3, and a second inductor L5_B is coupled between node N3 and a node N4. In addition, switch S3 is configured to selectively couple node N2 to node N3. Stated another way, switch S3 may be across inductor L6. Moreover, inductor L7 is coupled between a node N5 and a node N6 and inductor L8 is coupled between node N6 and a node N7, which is further coupled to a ground voltage GRND. Switch S4 is configured to selectively couple node N6 to node N7. Stated another way, switch S4 may be across inductor L8. It is noted that each of switch S3 and switch S4 may comprise one or more switches.

According to one exemplary embodiment of the present invention, mixer 302, which, as noted above may comprise a Gilbert cell mixer, an amplifier, or both, may be used to drive an antenna load directly for area reduction, and device 304 may compensate for 3 db conversion loss and rejection for common mode noise of mixer 302. Furthermore, multiband tuning may be achieved by switching inductors of the balun windings. More specifically, for example, for low-frequency band (LB), switches S3 and S4 may be in an open configuration. For mid-band (MB) and high-band (HB) frequencies, switches S3 and S4 may be closed (i.e., shorted). Stated another way, for MB and HB frequencies, inductor L6 may be shorted out via closing switch S3, and inductor L8 may be shorted out via closing switch S4.

It is noted that in one exemplary embodiment, as illustrated in FIG. 4A, both inductors L5_A and L5_B of primary winding 305 are configured to couple to inductor L7 of secondary winding 307, and inductor L6 of primary winding 305 is configured to couple to inductor L8 of secondary winding 307, wherein L5_A*L5_B=L7 and L6=L8. Accordingly, while switches S3 and S4 are open, inductors L5_A and L5_B may magnetically couple with inductor L7, and inductor L6 may couple with inductor L8. Further, while switches S3 and S4 are closed, inductors L5_A and L5_B may magnetically couple with inductor L7, and inductors L6 and L8 may be shorted out. Moreover, as will be appreciated by a person having ordinary skill in the art, a tuning range may be provided by sqrt[(L5_A*L5_B+L6)/(L5_A*L5_B)].

As will be appreciated by a person having ordinary skill in the art, device 304, and, more specifically, primary winding 305 and secondary winding 307 together include a single reactive passive element for providing multiband impedance matching. Further, device 304 may provide for a multiband matching network while using relatively small silicon (Si) area. Further, compared to various conventional matching networks, device 304 may have reduced insertion loss. Also, as will be appreciated by a person having ordinary skill in the art, when switch S3 is open, a voltage across inductor L6 (“V_N2toN3”) (i.e., from node N2 to node N3) may be equal to a voltage across the plurality of inductors in primary winding 305 (“V_N1toN4”) (i.e., from node N1 to node N4)*[L6/(L5_A*L5_B+L6)]. Accordingly, a voltage swing across switch S3 is scaled by a factor of L6/(L5_A*L5_B+L6). Therefore, the switches of device 304 (i.e., switches S3 and S4) operate at lesser swings compared to conventional devices, and, thus, the reliability of switch operation in an “off” mode is enhanced. As will be appreciated by a person having ordinary skill in the art, when switch S3, which is across inductor L6, is open, voltage swings at node N2 and node N3 are of the same magnitude with opposite phases, which adds power efficiently in secondary winding 307. Further, when switch S3 is shorted, voltage swings at node N1 and node N4 are equal in magnitude and opposite in phase, which adds power efficiently in secondary winding 307. In contrast, if switch S3 is across either inductor L5_A or inductor L5_B and in an open configuration, voltage swings at node N1 and node N4 are not of the same magnitude and opposite phases, which may degrade power efficiency of a balun and may degrade harmonic cancellation as well. Further, in an embodiment wherein switch S3 is across either inductor L5 A or inductor L5 B and in a shorted configuration, a voltage swing at node N1 is lower than a voltage swing at node N4 by a factor of (L1/0.5*L2+1). These asymmetric voltage swings at node N1 and node N4 may degrade eventual power delivery by a balun and may also degrade harmonic rejections.

FIG. 4B illustrates a device 350, according to another exemplary embodiment of the present invention. Device 350, which may comprise, for example only, a matching network, may also include mixer 302 coupled to a device 354. Like device 304, device 354 includes a primary winding 355 and a secondary winding 357. Further, device 354 includes a plurality of switches (i.e., S1p-SNp) coupled to primary winding 355 and a plurality of switches coupled to secondary winding (S1l-SNs). It is noted that for N switches coupled to primary winding 355, primary winding 355 may include 2*N+1 inductors. Further, for N switches coupled to secondary winding 357, secondary winding 357 may include N+1 inductors. In comparison to device 304, which may be configured for tuning between two frequency bands, device 354 may be configured for tuning between N frequency bands.

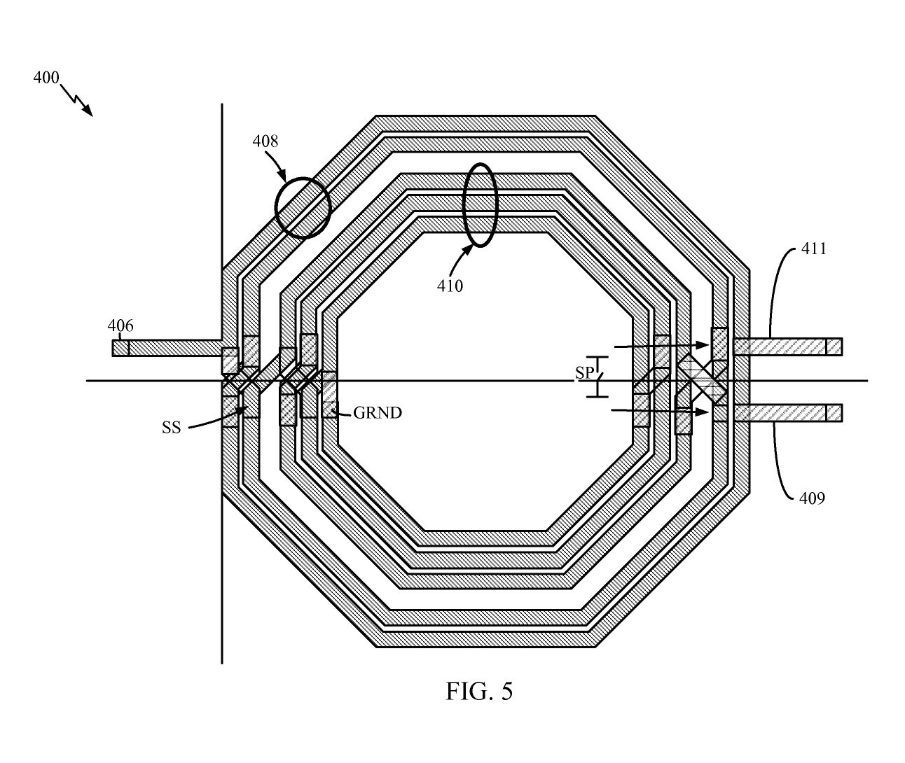

FIG. 5 illustrates a device 400, according to an exemplary embodiment of the present invention. By way of example, device 400 may comprise device 304 as illustrated in FIG. 4. Device 400, which may comprise a balun, may include inputs 409 and 411, which may be coupled to outputs of a mixer, such as a Gilbert cell mixer. According to one example, inputs 409 and 411 may comprise differential inputs. Further, device 400 includes a ground voltage GRND and an output 406, which may be coupled to, for example, an antenna. Device 400 also includes a primary winding, a secondary winding, and switches SP and SS. As one example, a primary winding of device 400 may comprise primary winding 305 illustrated in FIG. 4. Further, the secondary winding of device 400 may comprise secondary winding 307 illustrated in FIG. 4. As an example, switch SP may comprise a switch coupled to a primary winding. More specifically, for example, switch SP may comprise switch S3 of device 304 (see FIG. 4). Furthermore, switch SS may comprise a switch coupled to a secondary winding. More specifically, switch SS may comprise switch S4 of device 304 (see FIG. 4).

In addition, according to one example, device 400 includes coils 408, which may comprise inductor L5 of the primary winding (e.g., primary winding 305 of FIG. 4) in an M5 metal layer and inductor L7 of the secondary winding (e.g., secondary winding 307 of FIG. 4) in an API metal layer, as will be appreciated by a person having ordinary skill in the art. Moreover, device 400 may include coils 410, which may comprise inductor L6 of the primary winding (e.g., primary winding 305 of FIG. 4) in an M5 metal layer and inductor L8 of the secondary winding (e.g., secondary winding 307 of FIG. 4) in an API metal layer, as will be appreciated by a person having ordinary skill in the art.

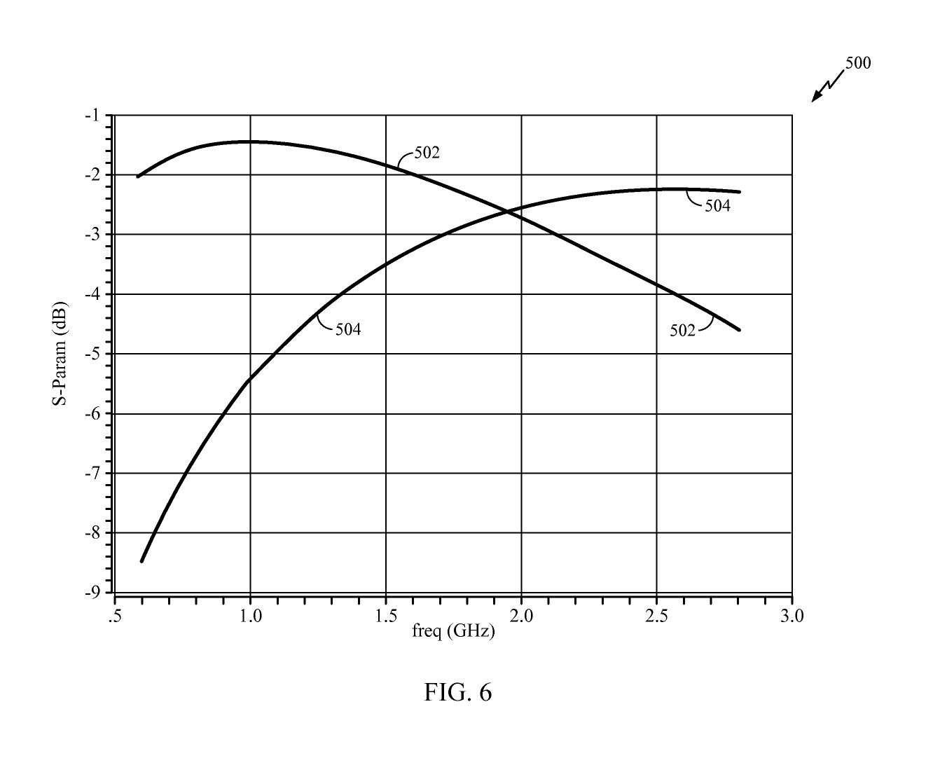

FIG. 6 is a plot 500 depicting an insertion loss (depicted by numeral 502) for a device (e.g., device 300) in a first configuration (i.e., with each of switch S3 and switch S4 in an open configuration) and an insertion loss (depicted by numeral 504) for the device (e.g., device 300) in a second configuration (i.e., with each of switch S3 and switch S4 in a closed configuration). As illustrated in plot 500, the insertion loss of the device in the first configuration (i.e., with each of switch S3 and switch S4 in an open configuration) is between approximately −1.5 dB and −2.5 dB from approximately 0.6 GHz to approximately 1.95 GHz. Further, the insertion loss of the device in the second configuration (i.e., with each of switch S3 and switch S4 in closed configuration) is between approximately −2.5 dB and −2.2 dB from approximately 1.95 GHz to approximately 2.8 GHz. Thus, the device, being properly configured, exhibits a low insertion loss across a frequency range of 0.6 GHz-2.8 GHz.

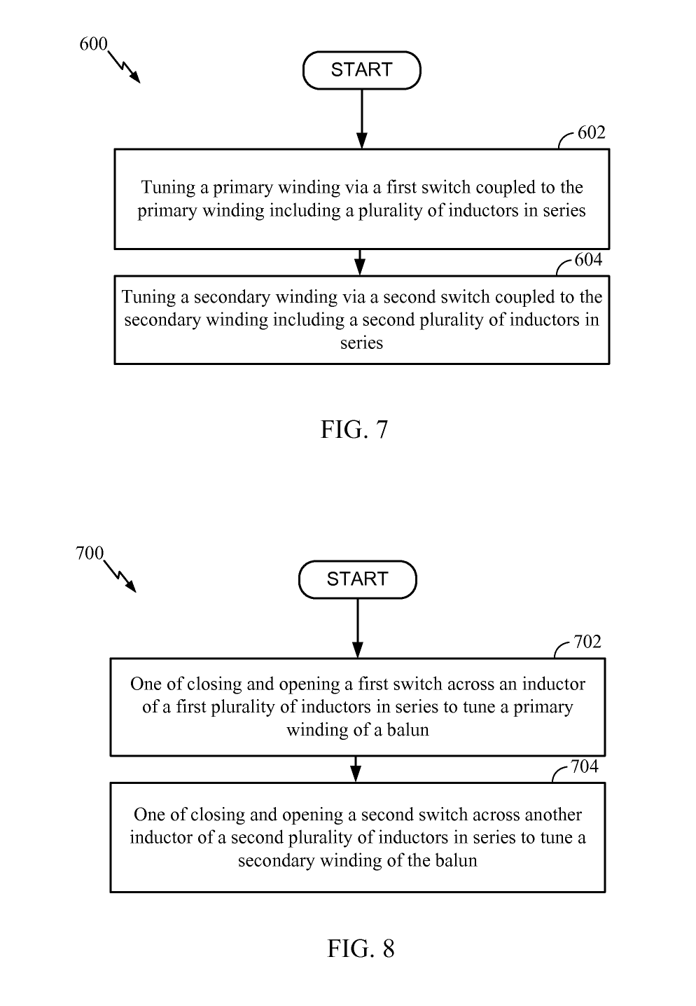

FIG. 7 is a flowchart illustrating a method 600, in accordance with one or more exemplary embodiments. Method 600 may include tuning a primary winding via a first switch coupled to the primary winding including a plurality of inductors in series (depicted by numeral 602). More specifically, for example, method 600 may include tuning a primary winding of a balun including a first plurality of coils in series via shorting out a coil of the first plurality of coils. Method 600 may also include tuning a secondary winding via a second switch coupled to the secondary winding including a second plurality of inductors in series (depicted by numeral 604). More specifically, for example, method 600 may include tuning a secondary winding of the balun including a second plurality of coils in series via shorting out a coil of the second plurality of coils.

FIG. 8 is a flowchart illustrating a method 700, in accordance with one or more exemplary embodiments. Method 700 may include one of closing and opening a first switch across an inductor of a first plurality of inductors in series to tune a primary winding of a balun (depicted by numeral 702). More specifically, for example, method 700 may include closing the first switch while operating in a MB frequency or HB frequency, and opening the first switch while operating in a LB frequency. Method 700 may also include one of closing and opening a second switch across another inductor of a second plurality of inductors in series to tune a secondary winding of the balun (depicted by numeral 704). More specifically, for example, method 700 may include closing the second switch while operating in a MB frequency or HB frequency, and opening the second switch while operating in a LB frequency.

As will be appreciated by a person having ordinary skill in the art, the present invention includes various advantages over conventional devices. For example, the present invention may require less area than device 100 (see FIG. 1), which requires two parallel coils to achieve the same tuning range. For example, the silicon area of device 304 (see FIG. 4) may be approximately half that of device 100. Moreover, as will be understood by a person having ordinary skill in the art, the switches of device 100 are required to experience a full swing when particular windings are off, thus, increasing distortion levels and putting reliability constraints on the switches. Accordingly, this may limit the use of device 100 for high voltage applications. In contrast, the switches of device 304 may only require a scaled down voltage swing when off, hence improving distortion levels and reliability. Furthermore, inactive coils of device 304 may be shorted out, thus reducing loss compared to device 100, which loads active coils with inactive coils. In addition, for a tuning range of 0.7 GHz-2.7 GHz, device 200 (see FIG. 2) may require an inductor value to switch by an order of 16, which may result in 12 dB higher insertion loss for 2.7 GHz band in comparison to device 304.

Those of skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill will further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A device, comprising:
a primary winding including a first plurality of inductors in series;
one or more switches coupled to the primary winding and configured to tune the primary winding to a frequency band of a plurality of frequency bands;
a secondary winding including a second plurality of inductors in series, the primary winding and the secondary winding comprising a single reactive passive element; and
one or more switches coupled to the secondary winding and configured to tune the secondary winding to the frequency band.

2. The device of claim 1, further comprising at least one of a Gilbert Cell mixer and an amplifier having an output coupled to the primary winding.

3. The device of claim 1, further comprising a capacitor coupled in parallel with the primary winding and another capacitor coupled in parallel with the secondary winding.

4. The device of claim 1, the first plurality of inductors comprising a first, second, and third inductor, wherein the second inductor is coupled between the first inductor and the third inductor.

5. The device of claim 4, a first switch of the one or more switches coupled to the primary winding configured to couple one end of the first inductor to one end of the third inductor.

6. The device of claim 5, the first switch comprising one or more switches across the second inductor and configured to short out the second inductor.

7. The device of claim 1, the second plurality of inductors comprising a first and second inductor, wherein a first end of the first inductor is coupled to an output, a second end of the first inductor is coupled to a first end of the second inductor, and a second end of the second inductor is coupled to a ground voltage.

8. The device of claim 7, a second switch of one or more switches coupled to the secondary winding configured to couple each of the second end of the first inductor and the first end of the second inductor to the ground voltage.

9. The device of claim 8, the second switch comprising one or more switches across the second inductor and configured to short out the second inductor.

10. The device of claim 1, wherein each of the first switch and the second switch is in an open configuration during a low-band (LB) frequency.

11. The device of claim 1, wherein each of a first switch of the one or more switches coupled to the primary winding and a second switch of the one or more switches coupled to the secondary winding is in a closed configuration during either a mid-band (MB) frequency or a high-band (HB) frequency.

12. The device of claim 1, further comprising a radio-frequency (RF) module including the primary and secondary windings and the one or more switches coupled to the primary winding and the one or more switches coupled to the secondary winding.

13. A method, comprising:
tuning a primary winding via a first switch coupled to the primary winding including a first plurality of inductors in series; and
tuning a secondary winding via a second switch coupled to the secondary winding including a second plurality of inductors in series, the primary winding and the secondary winding comprising a single reactive passive element.

14. The method of claim 13, the tuning a primary winding includes opening the first switch for operating in a low-frequency band and closing the first switch for operating in one of a mid-frequency band and a high-frequency band.

15. The method of claim 13, the tuning a secondary winding includes opening the second switch for operating in a low-frequency band and closing the second switch for operating in one of a mid-frequency band and a high-frequency band.

16. The method of claim 13, the tuning a primary winding comprising tuning the primary winding of a balun and tuning the secondary winding comprising tuning the secondary winding of the balun.

17. The method of claim 13, the tuning the primary winding comprising one of closing and opening the first switch across an inductor of the first plurality of inductors and the tuning a secondary winding comprising one of closing and opening the second switch across an inductor of the second plurality of inductors.

18. A device, comprising:
means for tuning a primary winding via a first switch coupled to the primary winding including a first plurality of inductors in series; and
means for tuning a secondary winding via a second switch coupled to the secondary winding including a second plurality of inductors in series, the primary winding and the secondary winding comprising a single reactive passive element.

19. The device of claim 18, the means for tuning the primary winding comprising means for selectively shorting out one inductor of the first plurality of inductors.

20. The device of claim 18, the means for tuning the secondary winding comprising means for selectively shorting out one inductor of the second plurality of inductors.
